(19) United States
(12) Patent Application Publication
(10) Pub. No.: US 2008/0142370 A1
(43) Pub. Date: Jun. 19, 2008

(54) Aqueous, Acidic Solution and Method for Electrolytically Depositing Copper Coatings as Well as Use of Said Solution

(76) Inventors: Wolfgang Dahms, Berlin (DE); Carl Christian Fels, Berlin (DE); Gunther Bauer, Berlin (DE)

Correspondence Address: Frank J. Bonini, Jr.;Harding, Earley, Follmer & Frailey, 86 The Commons at Valley Forge East, 1288 Valley Forge Road, Post Office Box 750, Valley Forge, PA, 19482-0750, US

(21) Appl. No.: 10/566,913

(22) PCT Filed: Jul. 28, 2004
(86) PCT No.: PCT/EP04/08492

§ 371 Date: Feb. 3, 2006

(30) Foreign Application Priority Data
Aug. 8, 2003 (DE) 103 37 669.0

(51) Int. Cl. C25D 5/00; C25D 3/38; H05K 1/09

(52) U.S. Cl. 205/137; 205/296; 205/298; 174/257

(57) ABSTRACT

The aqueous acidic solution for electrolytically depositing high polish, decorative bright, smooth and level copper coatings on large area metal or plastic parts contains a) at least one oxygen-containing, high molecular additive and b) at least one water soluble sulfur compound, wherein the solution additionally contains c) at least one aromatic halogen derivative having the general formula (I), wherein R₁, R₂, R₃, R₄, R₅ and R₆ are each independently radicals selected from the group comprising hydrogen, aldehyde, acetyl, hydroxyls, hydroxyalkyl having 1-4 carbon atoms, alkyl having 1-4 carbon atoms and halogen, with the proviso that the number of residues R₁, R₂, R₃, R₄, R₅ and R₆ which are halogen ranges from 1 to 5.

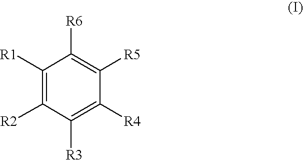

The present invention relates to an aqueous, acidic solution and to a method of electrolytically depositing copper coatings as well as to the use of said solution. Both solution and method preferably serve to produce high polish, decorative bright, smooth and level surfaces on large area metal or plastic parts as well as to coat printed circuit board material.

Various methods and deposition solutions are being used to produce decorative bright, smooth and level surfaces, more, specifically large area surfaces, on metals or plastics or to form ductile layers such as for subsequent metallization.

To this day, acid copper electrolyte solutions, more specifically the widespread sulfuric acid copper electrolyte solutions have been used forming bright copper coatings. In order to avoid formation of undesirable crystalline matte deposits, small amounts of certain organic substances are added to these solutions. At first, for example cellulose, dextrine, gelatine, adhesive glue and molasses were used therefore, followed later by thiourea and the derivatives thereof, organic sulfides and quaternary nitrogen compounds. The relevant literature further mentions polyvinyl alcohol, organic phosphorus compounds and organic dyes like Janus green or crystal violet as additives (see “Kupferschichten—Abscheidung, Eigenschaften, Anwendung”, (“Copper layers deposition, properties, application”), N. Kanani, Leuze-Verlag, pages 93 and 76 and “Handbuch der Galvanotechnik”—(“Manual of Electroplating”), Dettner, Elze, Carl Hanser Verlag, vol. II, page 65).

In the light of the ever increasing demands that are placed on the quality of the metal layers and surfaces formed, these solutions have no importance whatsoever in today's practice since the quality of the copper coatings obtained using them does not meet today's requirements. For these coatings are either too brittle or not bright enough or, in certain, current density ranges, the coatings obtained show a kind of relief.

Various other solutions have been tested to meet the new requirements. It has become known to add polyalkylene imines in combination with organic thio compounds (DE 1 246 347 A) and polyvinyl compounds in combination with oxygen-containing high molecular compounds and organic, more specifically aromatic, thio compounds (DE 1 521 062 A). Such type copper electrolyte solutions do not allow for utilization of higher cathodic current densities, though. Another disadvantage is that the deposited copper coatings must be subjected to an intermediate treatment prior to being metal plated, e.g., nickel-plated.

DE 1 521 0.62 A describes an acidic copper bath that contains, in .addition to an oxygen-containing polymeric compound, at least one substituted phenazinium compound.

Using the described monomeric phenazinium compounds in copper plating electrolytes, problems arise practicing the process. It has been recognized that the current density that may be applied as well as the aging behavior of the deposited metal layers may still be optimized.

Combinations of organic thio compounds and non-ionogenic wetting agents with other dyes such as crystal violet (EP 0 071 512 A1), amides (DE 27 46 938 A1) or phthalocyanine derivatives with aposafranine (DE 34 20 999 A1) are further used for depositing copper.

Further EP 1 300 486 A1 and EP 1 300 487 A1 disclose metal plating baths, more specifically copper plating baths, which comprise additive consumption inhibiting aldehyde or alcohol, respectively. Among a multitude of expressly disclosed aldehydes or alcohols, respectively, 2-chloro-4-hydroxybenzaldehyde as well as 4-chlororesorcinol, α,α,α(-trifluoro-m-cresol and 3-chlorophenol are mentioned exemplarily. The aldehydes or alcohols are comprised in the baths at a concentration of 0.001- 100 g/l. Examples show that these compounds are contained at a concentration of 1 g/l.

Undefined reaction products of polyamines with benzyl chloride (DE 25 41 897 A1) or with epichlorohydrin (E.P 0 068 807 A1), respectively, or reaction products with thio compounds and acrylamide (EP 0 107 109 A1) are also used in lieu of the dye.

The major disadvantage of the last mentioned solutions, more specifically when combined with nitrogen-containing thio compounds, is non-uniform deposition of the copper layer onto the surface of a substrate.

DE 20 39 831 C describes how the quality of the metal surfaces deposited may fee enhanced using polymeric phenazinium compounds. In the plating bath, these polymeric phenazinium compounds are mainly utilized in combination with non-ionogenic wetting agents and organic sulfur compounds.

A prerequisite of producing smooth surfaces is that the solution permits high leveling of the surface to be coated. High leveling however yields surfaces having a disadvantageous fine roughness (pittings, nodules) that severely affects the decorative appearance of large area parts in particular.

It has been recognized that this roughness is not due to particles suspended in the electrolyte as such a roughness could not be readily avoided by filtering the electrolyte. The fine roughness that forms with high leveling is due to a spontaneously disturbed deposition—which is also discussed to be a disguised whisker formation—in the cathodic double layer and particularly occurs with thicker copper layers having a thickness in excess of 5 μm. A corresponding defect may be recognized in the polished cross section of the metal layer deposited, said defect becoming apparent in the form of nodules or pittings on the surface as the other layers are being deposited. These pittings and nodules are particularly apparent on polished large area steel and plastic parts where the mirror-bright polish of the deposit even further emphasizes this effect.

This phenomenon was particularly observed using nitrogen-containing sulfur compounds (thiourea derivatives) and phenazinium compounds in plating electrolyte solutions. To circumvent this drawback DE 40 32 864 A1 discloses the use of special non-ionogenic wetting agents, in the present case more specifically of naphthol ethoxylates.

It has been recognized though that, when used in effective concentrations, the naphthol ethoxylates result in disturbing anode effects such that the anode film may completely come off or that the anode dissolves non-uniformly, which is not desirable.

Accordingly, using the known methods and treatment solutions, it is not possible to produce decorative bright and level metal surfaces that have no undesirable effects such as pittings and nodules. Using the known solutions, it is not possible to achieve high leveling without compromising the bright appearance of the surface layer. Moreover, both solution and method are intended to save costs and their process reliability must be high.

It is therefore the object of the present invention to avoid the prior art drawbacks. The invention more specifically aims at providing a solution and a method of deposition that permit advantageous high leveling of the surface to be coated while concurrently preventing fine roughness from forming, so that decorative bright metal surfaces may be formed on metal or plastic substrates and ductile metal layers on printed circuit board material.

In overcoming these problems, the invention provides the solution for depositing copper coatings in accordance with claim 1, the method in accordance with claim 24 and the use of the solution in accordance with claims 21 and 22. Preferred embodiments of the invention will become apparent in the dependant claims.

The solution of the invention is an aqueous acidic solution (electrolyte solution) and serves to electrolytically deposit bright copper coatings in particular, preferably decorative bright copper coatings, on large area metal or plastic parts such as in the automobile, the furniture or the sanitary industry, e.g., for metallizing automobile bumpers or shower heads as well as to deposit copper on printed circuit board material. The solution of the invention contains at least one oxygen-containing, high molecular additive and at least one water soluble sulfur compound, the solution additionally containing at least one aromatic halogen derivative having the general formula (I)

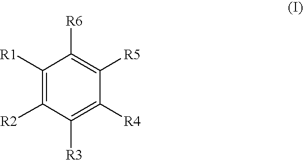

wherein R₁, R₂, R₃, R₄, R ₅ and R₆ are each independently radicals selected from the group comprising hydrogen, aldehyde, acetyl, hydroxy, hydroxyalkyl having 1-4 carbon atoms, alkyl having 1-4 carbon atoms and halogen, with the proviso that the number of radicals R₁, R₂, R₃,, R₄, R₅ and R₆ which are halogen ranges from 1-5.

If several radicals are halogen, the preferred number of radicals R₁, R₂, R₃,, R₄, R₅ and R₆ which maybe halogen ranges from one to three, more preferably from one to two. One halogen is most preferred.

The amount of the at least one aromatic halogen derivative, or of the salt thereof respectively, that is to be added to significantly improve copper deposition is extremely low. The concentration thereof ranges preferably from about 0.005 to about 0.9 mg/l, more preferably from about 0.005 to about 0.5 mg/l, a concentration of about 0.02 or more being particularly preferred, a concentration of about 0.3 mg/l or less being even more preferred and a concentration in the range of from about 0.02 to about 0.2 mg/l being most preferred.

Surprisingly, fine roughness could be prevented from forming using but small amounts of aromatic halogen derivatives. The proof of the effectiveness of the copper deposition can be furnished using cyclic voltammetry. The addition in accordance with the invention of aromatic halogen derivatives inhibits copper deposition, which becomes apparent as the stripping peak shifts toward anodic potentials. In addition, by adding aromatic halogen derivatives, the quotient of the anodic charge in the dissolution area (stripping peak) and of the cathodic charge in the deposition area (plating peak) increases from 93 to 100%. High polish leveled copper coatings (without any nodules and pittings) are produced as a result thereof.

Whereas the aromatic halogen derivatives having hydroxy groups at the aromatic compound (halogen phenol derivatives) act spontaneously, the action of the aldehydic substituted aromatic halogen derivatives is slightly delayed. This points to the fact that the hydroxy compounds constitute the active substances and that they can also be formed in the solution by reducing the aldehyde derivatives. Such theoretic considerations will not affect the scope of the invention, though. The structure of the copper crystallites on the surface to be coated changes during deposition. The grain boundaries formed are finer and the crystallites are generally smaller.

The method in accordance with the invention is simple, easy to perform and cheap. It serves to deposit high polish copper coatings on metal or plastic surfaces, the surfaces being brought into contact with the solution of the invention and copper being electrolytically deposited onto the surfaces.

The metal or plastic surfaces to be coated preferably include large area surfaces pertaining for example to the field of the automobile, toy, furniture or sanitary industry. The bright copper coatings more specifically serve decorative purposes, for example on coated automobile bumpers, automobile spoilers or wind deflectors, toys, shower heads, towel racks, and so on.

The metal or plastic surfaces also include surfaces of printed circuit boards. In this field, throwing power improves using both direct current and pulsed current for copper deposition.

The solution in accordance with the invention and the method permit to eliminate the problems arising using the known means. They more specifically permit to form high polish, decorative surfaces on metal and plastic surfaces while avoiding the formation of quality impairing effects such as nodules and pittings. Concurrently, besides high leveling, fine roughness is prevented from forming.

In order to achieve, for the solution of the invention, the deposition effect described, the aromatic halogen derivatives each independently contain substituted radicals. The radicals R₁, R₂, R₃, R₄, R₅ and R₆ present at the aromatic halogen derivatives may concurrently be the same and different.

Halogen is preferably selected from the group comprising fluorine, chlorine, bromine and iodine, with chlorine and bromine being particularly preferred.

The aldehyde radicals are thereby preferably selected from the group comprising formyl (—CHO), methylformyl (—CH₂—CHO) and ethylformyl (—C₂H₄—CHO).

The alkyl radicals are preferably selected from the group of branched and unbranched carbon chains having 1-4 carbon atoms, comprising methyl, ethyl, n-propyl, iso-propyl, n-butyl, iso-butyl and tert-butyl.

The hydroxyalkyl radicals preferably comprise branched or unbranched carbon chains having 1-4 carbon atoms, corresponding to the previously mentioned carbon chains of the alkyl radicals mentioned hereinbefore, each of the alkyl radicals mentioned hereinbefore containing at least one hydroxy group. Preferably, at least one hydroxyalkyl radical is a hydroxymethyl.

If the aromatic halogen derivatives according to the general formula (I) are used in the solution of the invention, the following compounds are particularly suited.

Aromatic Halogen Derivatives:
2-chlorobenzaldehyde
2-chlorophenol
4-chloro-3-methylphenol
2-chloro-4,5-dimethylphenol
4-chloro-3,5-dimethylphenol
4-chlorophenol
3-chlorophenol
o- chloroacetophenone
2-chlorobenzyl alcohol
4-bromo-2,6-dimethylphenol
4-bromophenol
2,4-dichlorobenzyl alcohol
2,6-dibromo-4-methylphenol
2,5-dichlorophenol
3,5-dibromobenzaldehyde
2,5-dibromobenzoic acid
2,4,6-trichlorophenol
2,3,6-trichlorobenzaldehyde

Before use the aromatic halogen, derivatives are preferably dissolved in methanol or in other alcohols (e.g., glycol) or polyalcohols (e.g., polyethylene glycol) and then added to the solution of the invention. To dissolve the aromatic halogen derivatives in the solution of the invention, it is often helpful to alkalinize the solution, certain amounts of salts that are readily soluble in water such as alkali halogen phenolates forming in the process. A bisulfite adduct forming with the CO-group of the aldehyde radical may also be used to improve water solubility with, possibly, partial formation of α-hydroxysulfonates. Partial acetal formation may also occur if aldehyde-containing aromatic halogen derivatives are dissolved in alcohol.

The aromatic halogen derivatives are actually known and are mostly commercially available or may be produced according to known methods.

The current brighteners, wetting agents or levellers also enhance other physical properties such as the ductility of the layers for example. Examples of these compounds are oxygen-containing, high molecular additives and water soluble sulfur compounds.

The at least one oxygen-containing high molecular additive contained in the solution of the invention preferably is a polyalkylene glycol compound, for example a polyalkylene glycol or an acid ester, more specifically carboxylic acid ester or alcohol ether, such as alkanol ether or phenol ether, of a polyalkylene glycol. The additive is more specifically selected from the group comprising

Oxygen-containing high molecular additives:
polyvinyl alcohol
carboxymethyl cellulose
polyethylene glycol
polypropylene glycol
stearic acid polyglycol ester
oleic acid polyglycol ester
stearyl alcohol polyglycol ether
nonylphenol-polyglycol ether
octanol polyalkylene glycol ether
octanediol-bis-(polyalkylene glycol ether)
poly(ethylene glycol-ran-propylene glycol)
poly(ethylene glycol)-block-poly(propylene glycol)-block-poly(ethylene glycol)
polypropylene glycol)-block-poly(ethylene glycol)-blocl-poly(propylene glycol)

The amount of the at least one oxygen-containing high molecular additive preferably corresponds to a concentration range of from about 0.005 to about 20 g/l, more preferably to a concentration range of from about 0.01 to about 5 g/l.

The at least one water soluble sulfur compound contained in the solution of the invention is preferably selected from the group comprising organic, nitrogen-free thio compounds and the salts thereof. The salts preferably contain alkali or earth alkali metal ions, selected from the group comprising sodium, potassium, magnesium and calcium.

The salts of the following organic nitrogen-free thio compounds are particularly suited:
Organic nitrogen-free thio compounds:
sodium salt of 3-(benzthiazolyl-2-thio)-propylsulfonic acid
sodium salt of 3-mercaptopropane-1-sulfonic acid
disodium salt of thiophosphoric acid-O-ethyl-bis-(ω-sulfopropyl)-ester
trisodium salt of thiophosphoric acid-tris-(ω-sulfopropyl)-ester
sodium salt of ethylenedithio dipropyl sulfonic acid
disodium salt of bis-(p-sulfophenyl)-disulfide
disodium salt of bis-(ω-sulfopropyl)-sulfide
disodium salt of bis-(ω-sulfopropyl)disulfide
disodium salt of bis-(ω-sulfohydroxypropyl)-disulfide
disodium salt of bis-(ω-sulfobutyl)-disulfide
sodium salt of methyl-(ω-sulfopropyl)-disulfide
sodium salt of methyl-(ω-sulfobutyl)-trisulfide
potassium salt of O-ethyl-dithiocarbonic acid-S-(ω-sulfopropyl)-ester
thioglycolic acid.

The amount of the at least one water soluble sulfur compounds or of the salts thereof preferably corresponds to a concentration range of from about 0.0005 to about 0.4 g/l, more preferably to a concentration range of from about 0.001 to about 0.15 g/l.

The solution of the invention further contains at least one acid. Said acid is preferably selected from the group comprising sulfuric acid, hydrochloric acid, fluoboric acid and methanesulfonic acid.

The amount of the at least one acid, preferably of the sulfuric acid, preferably corresponds to a concentration range of from about 50 to about 350 g/l, more preferably to a concentration range of from about 180 to about 220 g/l or of from about 50 to about 90 g/l.

The solution of the invention may additionally contain chloride ions. The chloride ions are preferably added to the solution in the form of sodium chloride and/or of hydrochloric acid. The addition of sodium chloride may be dispensed with in part or in whole if chloride ions are already contained in other additives.

The copper ions needed for depositing copper coatings are provided either by copper salts, preferably copper sulfate, or by soluble copper anodes, which are preferably located in the conventional anode baskets inside or outside of the solution. Copper ions may also be supplied to the solution by chemically dissolving small pieces of copper in a separate container using atmospheric oxygen or iron(III) ions.

The basic composition of the solution of the invention may vary over wide limits as indicated. As a result and in addition to the concentration ranges given for the oxygen-containing high molecular additives, the water soluble sulfur compounds, the acids, preferably the sulfuric acid, and the aromatic halogen derivatives, the aqueous acidic solution of the invention generally further contains: copper sulfate (CuSO₄·5 H₂O) in a concentration range of preferably from about 20 to about 250 g/l, more preferably of from about 60 to about 80 g/l or from about 180 to about 220 g/l and chloride ions in a concentration range of preferably from about 0.02 to about 0.25 g/l, more preferably of from about 0.05 to about 0.12 g/l.

Other copper salts than copper sulfate may be used in part. The sulfuric acid can also be replaced, in part or in whole, with fluoboric acid, methanesulfonic acid, hydrochloric acid or by other acids.

In order to further enhance levelling of the surfaces to be coated, the solution of the invention may contain other additional levellers either together or individually. At least one nitrogen-containing thio compound, at least one polymeric phenazinium compound and/or at least one polymeric nitrogen compound are preferably added to the solution of the invention.

Particularly suited nitrogen-containing thio compounds are:

Nitrogen-containing thio compounds (thiourea derivatives):
thiourea
N-acetylthiourea
N-trifluoroacetyl thiourea
N-ethylthiourea
N-cyanoacetyl thiourea
N-allylthiourea
o-tolylthiourea
N,N′-butylene thiourea
thiazolidine thiol-2
4-thiazoline thiol-2
imidazolidine thiol-2-(N,N′-ethylene thiourea)
4-methyl-2-pyrimidine thiol
2-thiouracil

The amount of the at least one nitrogen-containing thio compound preferably corresponds to a concentration range of from about 0.0001 to about 0.5 g/l, more preferably to a concentration range of from about 0.005 to about 0.04 g/l.

Particularly suited polymeric phenazinium compounds are:

Polymeric phenazinium compounds:
poly(6-methyl-7-dimethylamino-5-phenyl-phenazinium sulfate)
poly(2-methyl-7-diethylamino-5-phenyl-phenazinium chloride)
poly(2-methyl-7-dimethylamino-5-phenyl-phenazinium sulfate)
poly(5-methyl-7-dimethylamino-phenazinium acetate)
poly(2-methyl-7-anilino-5-phenyl-phenazinium sulfate)
poly(2-methyl-7-dimethylamino-phenazinium sulfate)
poly(7-methylamino-5-phenyl-phenazinium acetate)
poly(7-ethylamino-2,5-diphenyl-phenazinium chloride)
poly(2,8-dimethyl-7-diethylamino-5-p-tolyl-phenazinium chloride)
poly(2,5,8-triphenyl-7-dimethylamino-phenazinium sulfate)
poly(2,8-dimethyl-7-amino-5-phenyl-phenazinium sulfate)
poly(7-dimethylamino-5-phenyl-phenazinium chloride)

The amount of the at least one polymeric phenazinium compound preferably corresponds to a concentration range of from about 0.0001 to about 0.5 g/l, more preferably to a concentration range of from about 0.005 to about 0.04 g/l.

Particularly suited polymeric nitrogen compounds are:

Polymeric nitrogen compounds:
polyethylene imine
polyethylene imide
polyacrylic acid amide
polypropylene imine
polybutylene imine
N-methyl polyethylene imine
N-acetyl polyethylene imine
N-butyl polyethylene imine

The amount of the at least one polymeric nitrogen compound preferably corresponds to a concentration range of from about 0.0001 to about 0.5 g/l, more preferably to a concentration range of from about 0.005 to about 0.04 g/l.

In a preferred embodiment, the solution of the invention may contain, in addition to the basic composition described, oxygen-containing, high molecular additives, water soluble sulfur compounds, acids, copper sulfate, chloride ions and aromatic halogen derivatives, at least one of the nitrogen-containing thio compounds mentioned hereinbefore, at least one of the polymeric phenazinium compounds mentioned hereinbefore and at least one of the polymeric nitrogen compounds mentioned hereinbefore.

The electrolytic deposition of copper coatings is preferably performed under the following conditions:

| | |
|---|---|
| pH-value: | <1; |
| temperature: | from about 15 to about 50° C., |
| more preferably | from about 20 to about 33° C.; |
| cathodic current density: | from about 0.5 to about 12 A/dm², |
| more preferably | from about 2 to about 4 A/dm². |

Sufficient mixing of the solution of the invention during deposition is achieved by a strong flow and, at need, by blowing clean air into the mixture so that the surface of the solution is strongly agitated. As a result, the transport of substances in proximity to the electrodes is maximized, which makes it possible to achieve higher current densities. It is moreover possible to enhance the transport of substances at the respective surfaces by causing the cathodes to move. Thanks to the thus increased convection and to the movement of the electrodes, constant, diffusion-controlled deposition is performed. The electrodes may be moved horizontally, vertically and/or by vibration or ultrasound for example. This is particularly effective in combination with air being blown in.

The copper content of the solution of the invention can be electrochemically replenished, during deposition, using soluble copper anodes. The anode material used is preferably copper containing 0.02-0.06% phosphorus (m/m). In order to prevent dirt accumulation on the copper anodes, they should be sealed from the electrolyte by anode bags. Inert anodes may be used in the alternative. In this case, the copper content must be replenished from a separate dissolution compartment.

In order to maintain the quality of the solution of the invention, filters for retaining mechanical and/or chemical residues may be inserted into the solution's circulation system. If soluble copper anodes are used, filtration is highly recommended because the phosphorus causes anode sludge to form which can disturb the deposition process. Using inert anodes, the quality of the solution maybe maintained at less expense.

The work piece can be coated in horizontal or vertical conveyorized plating lines.

The following examples serve to explain the invention:

### COMPARATIVE EXAMPLE 1a

An aqueous acidic solution was prepared by mixing the following constituents:

| | | |
|---|---|---|
| copper sulfate (CuSO₄•5H₂O) | 200.0 | g |
| sulfuric acid (96% (m/m)) | 65.0 | g |
| sodium chloride | 0.2 | g |
| polyethylene glycol | 0.2 | g |
| disodium salt of bis-(ω-sulfopropyl)-disulfide | 0.01 | g |
| 7-dimethylamino-5-phenyl-phenazinium chloride (polymer) | 0.02 | g |
| and deionized water to bring the volume to 1 l. | | |

The solution was heated to 27° C. Then, in accordance with the method of the invention a polished brass plate was brought into contact with the solution.

Cathodic current density was 4 A/dm². During deposition, air was blown into the solution in order to achieve thorough mixing.

A well-leveled bright copper coating appeared on the brass plate which, on closer examination, showed fine roughness (pittings), though.

### EXAMPLE 1b

### Example in Accordance with the Invention

Comparative Example 1a was repeated with the same solution, except that the following aromatic halogen derivative was now added in accordance with the invention:

| | |
|---|---|
| 4-chloro-3,5-dimethylphenol | 0.1 mg |

Deposition resulted in a well-leveled, mirror polish copper coating. The coating showed no voids.

### COMPARATIVE EXAMPLE 1c

Comparative Example 1a was repeated. 76 mg/l of 4-chloro-3,5-dimethylphenol were added to the deposition solution. The deposit produced was not bright but rather had a mist-type appearance being comprised of a plurality of pittings and nodules.

### COMPARATIVE EXAMPLE 1d

Comparative Example 1a was repeated. 152 mg/l of 4-chloro-3,5-dimethylphenol were added to the solution. The deposit was matte and could therefore not be used as a decorative coating.

### COMPARATIVE EXAMPLE 2a

An aqueous acidic solution was prepared by mixing the following constituents:

| | | |
|---|---|---|
| copper sulfate (CuSO₄•5H₂O) | 80.0 | g |
| sulfuric acid (96% (m/m)) | 180.0 | g |
| sodium chloride | 0.08 | g |
| polypropylene glycol | 0.6 | g |
| sodium salt of 3-mercaptopropane-1-sulfonate | 0.02 | g |
| N-acetylthiourea | 0.003 | g |
| and deionized water to bring the volume to 1 l. | | |

The solution was heated to 30° C. Then, in accordance with the method of the invention a brushed copper laminate was brought into contact with the solution. Cathodic current density was 2 A/dm². During deposition, air was blown into the solution in order to achieve thorough mixing.

On the copper laminate there appeared a bright copper coating which however showed fine roughness (pittings and nodules).

### EXAMPLE 2b

### Example in Accordance with the Invention

Comparative Example 2a was repeated with the same solution, except that the following aromatic halogen derivative was now added in accordance with the invention:

| | |
|---|---|
| 2-chlorobenzaldehyde | 0.5 mg |

Deposition resulted in a well-leveled, mirror polish copper-coating. The coating showed no voids.

It is understood that the examples and embodiments described herein are for illustrative purpose only and that various modifications and changes in light thereof as well as combinations of features described in this application will be suggested to persons skilled in the art and are to be included within the spirit and purview of the described invention and within the scope of the appended claims. All publications, patents and patent applications cited herein are hereby incorporated by reference.

1. An aqueous acidic solution for electrolytically depositing copper coatings, said solution containing at least one oxygen-containing, high molecular additive and at least one water soluble sulfur compound, characterized in that the solution additionally contains at least one aromatic halogen derivative having the general formula 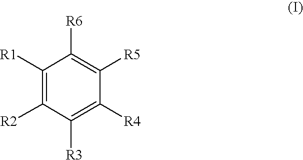
wherein R1, R2, R3, R4, R5 and R6 are each independently radicals selected from the group consisting of hydrogen, aldehyde, acetyl, hydroxy, hydroxyalkyl having 1-4 carbon atoms, alkyl having 1-4 carbon atoms and halogen, with the proviso that the number of radicals R1, R2, R3, R4, R5 and R6 which are halogen ranges from 1-5.

2. The solution according to claim 1, characterized in that the concentration of the at least one aromatic halogen derivative ranges from about 0.005-about 0.9 mg/l.

3. The solution according to claim 1, characterized in that the aldehyde is selected from the group consisting of formyl (—CHO), methylformyl (—CH₂—CHO) and ethylformyl (—C₂H₄—CHO).

4. The solution according to claim 1, characterized in that alkyl is branched or unbranched and is selected from the group consisting of methyl, ethyl, n-propyl, iso-propyl, n-butyl, iso-butyl and tert-butyl.

5. The solution according to claim 1, characterized in that the alkyl having 1-4 carbon atoms is hydroxyalkyl and that it is branched or unbranched.

6. The solution according to claim 1, characterized in that at least one hydroxyalkyl is hydroxymethyl.

7. The solution according to claim 1, characterized in that the at least one aromatic halogen derivative is selected from the group consisting of
2-chlorobenzaldehyde;
2-chlorophenol;
4-chloro-3-methylphenol;
2-chloro-4,5-dimethylphenol;
4-chloro-3,5-dimethylphenol;
4-chlorophenol;
3-chlorophenol;
o-chloroacetophenone;
2-chlorobenzyl alcohol;
4-bromo-2,6-dimethylphenol;
4-bromophenol;
2,4-dichlorobenzyl alcohol;
2,6-dibromo-4-methylphenol;
2,5-dichlorophenol;
3,5-dibromobenzaldehyde;
2,5-dibromobenzoic acid;
2,4,6-trichlorophenol; and
2,3,6-trichlorobenzaldehyde.

8. The solution according to claim 1, characterized in that the at least one oxygen-containing, high molecular additive is selected from the group consisting of polyvinyl alcohol; carboxymethyl cellulose; polyethylene glycol; polypropylene glycol; stearic acid polyglycol ester; oleic acid polyglycol ester; stearyl alcohol polyglycol ether; nonylphenol-polyglycol ether; octanol polyalkylene glycol ether; octanediol-bis-(polyalkylene glycol ether); poly(ethylene glycol-ran-propylene glycol); poly(ethylene glycol)-block-poly(propylene glycol)-block-poly(ethylene glycol); and poly(propylene glycol)-block-poly(ethylene glycol)-block-poly(propylene glycol).

9. The solution according to claim 1, characterized in that the at least one water soluble sulfur compound is selected from the group consisting of organic, nitrogen-free thio compounds and the salts thereof.

10. The solution according to claim 9, characterized in that the salts contain alkali or earth alkali metal ions, selected from the group consisting of sodium, potassium, magnesium and calcium.

11. The solution according to claim 9, characterized in that the at least one organic nitrogen-free thio compound is selected from the group consisting of sodium salt of 3-(benzthiazolyl-2-thio)-propylsulfonic acid; sodium salt of 3-mercaptopropane-1-sulfonic acid; disodium salt of thiophosphoric acid-O-ethyl-bis-(ω-sulfopropyl)-ester; trisodium salt of thiophosphoric acid-tris-(ω-sulfopropyl)-ester; sodium salt of ethylenedithio dipropyl sulfonic acid; disodium salt of bis-(ρ-sulfophenyl)-disulfide; disodium salt of bis-(ω-sulfopropyl)-sulfide; disodium salt of bis-(ω-sulfopropyl)-disulfide, disodium salt of bis-(ω-sulfohydroxypropyl)-disulfide; disodium salt of bis-(ω-sulfobutyl)-disulfide; sodium salt of methyl-(ω-sulfopropyl)-disulfide; sodium salt of methyl-(ω-sulfobutyl)-trisulfide; potassium salt of O-ethyl-dithiocarbonic acid-S-(ω-sulfoproyl)-ester; and thioglycolic acid.

12. The solution according to claim 1, characterized in that acid is contained in the solution and that the acid is selected form the group consisting of sulfuric acid, hydrochloric acid, fluoboric acid and methanesulfonic acid.

13. The solution according to claim 1, characterized in that the solution additionally contains chloride ions.

14. The solution according to claim 13, characterized in that the chloride ions have been added to the solution in the form of sodium chloride and/or of hydrochloric acid.

15. The solution according to claim 1, characterized in that the solution additionally contains at least one organic, nitrogen-containing compound.

16. The solution according to claim 15, characterized in that the at least one nitrogen-containing thio compound is selected from the group consisting of
thiourea;
N-acetylthiourea;
N-trifluoroacetyl thiourea;
N-ethylthiourea;
N-cyanoacetyl thiourea;
N-allylthiourea;
o-tolylthiourea;
N,N′-butylene thiourea;
thiazolidine thiol-2;
4-thiazoline thiol-2;
imidazolidine thiol-2-(N,N′-ethylene thiourea);
4-methyl-2-pyrimidine thiol; and
2-thiouracil.

17. The solution according to claim 1, characterized in that the solution additionally contains at least one polymeric phenazinium compound.

18. The solution according to claim 17, characterized in that the at least one polymeric phenazinium compound is selected from the group consisting of poly(6-methyl-7-dimethylamino-5-phenyl-phenazinium sulfate); poly(2-methyl-7-diethylamino-5-phenyl-phenazinium chloride); poly(2-methyl-7-dimethylamino-5-phenyl-phenazinium sulfate); poly(5-methyl-7-dimethylamino-phenazinium acetate); poly(2-methyl-7-anilino-5-phenyl-phenazinium sulfate); poly(2-methyl-7-dimethylamino-phenazinium sulfate); poly(7-methylamino-5-phenyl-phenazinium acetate); poly(7-ethylamino-2,5-diphenyl-phenazinium chloride); poly (2,8-dimethyl-7-diethylamino-5-p-tolyl-phenazinium chloride); poly(2,5, 8-triphenyl-7-dimethylamino-phenazinium sulfate); poly(2,8-dimethyl-7-amino-5-phenyl-phenazinium sulfate); and poly(7-dimethylamino-5-phenyl-phenazinium chloride).

19. The solution according to claim 1, characterized in that the solution additionally contains at least one polymeric nitrogen compound.

20. The solution according to claim 19, characterized in that the at least one polymeric nitrogen compound is selected from the group consisting of polyethylene imine, polyethylene imide, polyacrylic acid amide, polypropylene imine, polybutylene imine, N-methyl polyethylene imine, N-acetyl polyethylene imine, N-butyl polyethylene imine.

21. (canceled)

22. (canceled)

23. (canceled)

24. A method of electrolytically depositing copper coatings on metal or plastic surfaces, comprising bringing the surfaces into contact with the solution according to claim 1 and electrolytically depositing copper onto the surfaces.

25. The method of claim 23, wherein the metal or plastic surfaces are printed circuit board material.

26. The method of claim 23, wherein the method includes the step of moving said metal or plastic surfaces in vertical and/or horizontal conveyorized plating lines.

27. A printed circuit board having at least one surface with a copper coating thereon, which copper coating is applied by bringing the at least one surface into contact with the solution according to claim 1 and electrolytically depositing copper onto the surface.

28. The solution according to claim 10, characterized in that the at least one organic nitrogen-free thio compound is selected from the group consisting of sodium salt of 3-(benzthiazolyl-2-thio)-propylsulfonic acid; sodium salt of 3-mercaptopropane-1-sulfonic acid; disodium salt of thiophosphoric acid-O-ethyl-bis-(ω-sulfopropyl)-ester; trisodium salt of thiophosphoric acid-tris-(ω-sulfopropyl)-ester; sodium salt of ethylenedithio dipropyl sulfonic acid; disodium salt of bis-(p-sulfophenyl)-disulfide; disodium salt of bis-(ω-sulfopropyl)-sulfide; disodium salt of bis-(ω-sulfopropyl)-disulfide; disodium salt of bis-(ω-sulfohydroxypropyl)-disulfide; disodium salt of bis-(ω-sulfobutyl)-disulfide; sodium salt of methyl-(ω-sulfopropyl)-disulfide; sodium salt of methyl-(ω-sulfobutyl)-trisulfide; potassium salt of O-ethyl-dithiocarbonic acid-S-(ω-sulfoproyl)-ester; and thioglycolic acid.
